(19) United States
(12) Patent Application Publication
(10) Pub. No.: US 2008/0204112 A1
(43) Pub. Date: Aug. 28, 2008

(54) MoCA-COMPLIANT MULTIPLEXING DEVICE

(76) Inventors: Nan-Hsiang CHUNG, Feng Shan City (TW); Shuo-Chao HUANG, Ta Liao Hsiang (TW)

Correspondence Address: LADAS & PARRY LLP, 224 SOUTH MICHIGAN AVENUE, SUITE 1600, CHICAGO, IL, 60604, US

(21) Appl. No.: 11/678,639

(22) Filed: Feb. 26, 2007

(51) Int. Cl. H03K 17/62

(52) U.S. Cl. 327/407

(57) ABSTRACT

A multiplexing device complies with Multimedia over Coax Alliance (MoCA) specifications, and includes a circuit board disposed in a casing, first and second adapters disposed on the circuit board and adapted to be connected between an input end and an output end, and a shielding component. The first adapter includes a first low pass filter connected in series to a first high pass filter. The second adapter includes a second low pass filter connected in series to a second high pass filter. The shielding component is disposed on the circuit board between the first and second low pass filters, and has a height greater than that of the first and second adapters such that electromagnetic energy emitted by the first and second adapters is blocked to reduce undesired coupling between signals in the first and second adapters.

### BACKGROUND OF THE INVENTION

1. Field of the Invention

The invention relates to a multiplexing device, more particularly to a multiplexing device complying with Multimedia over Coax Alliance (MoCA) specifications.

2. Description of the Related Art

For years, Ethernet cables are primarily used in digital home wiring for transmission of audio-video signals and digital data among rooms in a premise and for connections among equipments, such as multimedia systems, automatic control systems, security systems, etc., in the premise.

However, Ethernet infrastructure has a disadvantage in that, when wiring an existing building structure, boring through walls inevitably damages the building structure, and the wiring operation may be more difficult to conduct compared to constructing a new structure. Moreover, the skills of professionals, instead of ordinary technicians, are needed when installing Ethernet cables, thereby resulting in higher installation costs.

Therefore, new technologies, such as the HomePlug Power Alliance (HomePlug AV) specifications and the Multimedia over Coax Alliance (MoCA) specifications, have been developed to overcome the aforesaid disadvantages of Ethernet cables. Instead of installing a new wiring network system, the HomePlug Av and MoCA specifications utilize transmission lines commonly found in existing building structures for digital signal transmission. In particular, the HomePlug Av specifications require use of ordinary transmission lines such as power lines from power companies, whereas the MoCA specifications require use of coaxial cable lines. According to the MoCA specifications, by coupling a MoCA-compliant multiplexer or adaptor to a coaxial cable, the coaxial cable can be used for telephone service and computer digital network applications and can provide sufficient bandwidth to satisfy remote control of audio-video data streams.

Referring to FIG. 1, a conventional MoCA-compliant multiplexer circuit 1 is shown to be adapted to be disposed between an input (INPUT) and a pair of outputs (OUTPUT). The multiplexer circuit 1 includes first and second adapters 10, 12. The first adapter 10 includes a first high pass filter (HPF1) connected to the input (INPUT), and a first low pass filter (LPF1) connected in series between the first high pass filter (HPF1) and one of the outputs (OUTPUT). The second adapter 12 includes a second high pass filter (HPF2) connected to the input (INPUT), and a second low pass filter (LPF2) connected in series between the second high pass filter (HPF2) and the other one of the outputs (OUTPUT). The first adapter 10 forms a 5 MHz to 860 MHz low pass frequency band, whereas the second adapter 12 forms a 975 MHz to 1525 MHz band pass frequency band.

Because the frequency bands of the conventional multiplexer circuit 1 are relatively wide, and because the frequency ranges thereof belong to a relatively high frequency range, the rate of change of signal frequencies in the frequency bands is relatively fast. The fast rate of change of signal frequencies can easily result in the release of electromagnetic energy for signals of different frequencies or in one of the frequency bands, and in emission of the electromagnetic energy to the surrounding environment by the corresponding filter. This phenomenon is more likely to occur in the higher frequency range (i.e., 975 MHz to 1525 MHz) of the second adapter 12, and can lead to undesirable coupling with signals in the lower frequency range (i.e., 5 MHz to 860 MHz) of the first adapter 10.

### SUMMARY OF THE INVENTION

Therefore, the object of the present invention is to provide a multiplexing device that can overcome the above drawback associated with the prior art.

According to the present invention, there is provided a multiplexing device complying with Multimedia over Coax Alliance (MoCA) specifications and adapted to be disposed between an input end and an output end. The multiplexing device comprises a casing, a circuit board disposed in the casing, first and second adapters, and a shielding component.

The first adapter is disposed on the circuit board, and is adapted to be connected between the input end and the output end. The first adapter includes a first high pass filter and a first low pass filter connected in series to the first high pass filter.

The second adapter is disposed on the circuit board, and is adapted to be connected between the input end and the output end. The second adapter includes a second high pass filter and a second low pass filter connected in series to the second high pass filter.

The shielding component is disposed on the circuit board between the first low pass filter of the first adapter and the second low pass filter of the second adapter. The shielding component has a height greater than that of the first and second adapters such that electromagnetic energy emitted by the first and second adapters is blocked to reduce undesired coupling between signals in the first and second adapters.

### BRIEF DESCRIPTION OF THE DRAWINGS

Other features and advantages of the present invention will become apparent in the following detailed description of the preferred embodiment with reference to the accompanying drawings, of which:

FIG. 1 is a block diagram of a conventional MoCA-compliant multiplexer circuit;

FIG. 2 is a schematic sectional view of the preferred embodiment of a MoCA-compliant multiplexing device according to the present invention;

FIG. 3 is a block diagram of the preferred embodiment; and

FIG. 4 is a plot of frequency versus noise response to compare the performances of the conventional multiplexer circuit and the present invention.

### DETAILED DESCRIPTION OF THE PREFERRED EMBODIMENT

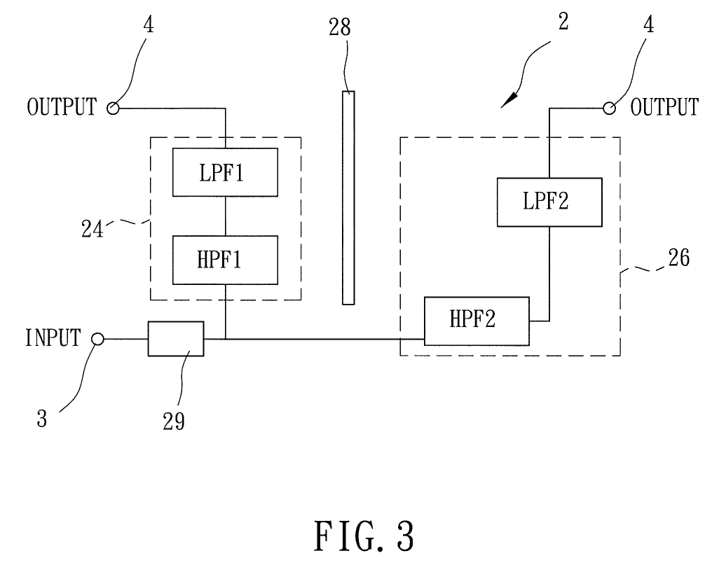

Referring to FIGS. 2 and 3, the preferred embodiment of a multiplexing device 2 complying with MoCA specifications according to the present invention is shown to be adapted to be disposed between an input end (INPUT) 3 and a pair of outputs (OUTPUT) 4 that serve as an output end. The multiplexing device 2 includes a casing 20, a circuit board 22, a first adapter 24, a second adapter 26, a shielding component 28, and a surge suppressor 29.

The casing 20 defines a receiving space 200. The circuit board 22 is disposed in the receiving space 200.

The first adapter 24 is disposed on the circuit board 22, and is connected between the input end 3 and one of the outputs 4. The first adapter 24 includes a first high pass filter (HPF1) and a first low pass filter (LPF1) connected in series to the first high pass filter (HPF1). Each of the first high pass filter (HPF1) and the first low pass filter (LPF1) is formed from a plurality of coils 240. The first adapter 24 permits signals within the frequency range of 5 MHz to 860 MHz to pass therethrough.

The second adapter 26 is disposed on the circuit board 22, and is connected between the input end 3 and the other one of the outputs 4. The second adapter 24 includes a second high pass filter (HPF2) and a second low pass filter (LPF2) connected in series to the second high pass filter (HPF2). Each of the second high pass filter (HPF2) and the second low pass filter (LPF2) is formed from a plurality of coils 260. The second adapter 26 permits signals within the frequency range of 975 MHz to 1525 MHz to pass therethrough.

The shielding component 28 is disposed on the circuit board 22 between the first low pass filter (LPF1) of the first adapter 24 and the second low pass filter (LPF2) of the second adapter 26. The shielding component 28 has a height greater than that of the coils 240, 260 of the first and second adapters 24, 26. In this embodiment, the shielding component 28 is in a form of a thin metal plate.

The surge suppressor 29 is disposed on the circuit board 22, and is connected between the input end 3 and each of the first and second adapters 24, 26.

In use, a signal at the input end 3 is fed simultaneously to the first and second adapters 24, 26 of the multiplexing device 2. Since the first adapter 24 forms a 5 MHz to 860 MHz low pass frequency band, and the second adapter 26 forms a 975 MHz to 1525 MHz band pass frequency band, most lower frequency signals pass through the first adapter 24 and most higher frequency signals pass through the second adapter 26.

As mentioned hereinabove, the shielding component 28 is disposed between the first low pass filter (LPF1) of the first adapter 24 and the second low pass filter (LPF2) of the second adapter 26, and has a height greater than that of the coils 240, 260 of the first and second adapters 24, 26. Therefore, electromagnetic energy released by signals in the higher frequency range (i.e., 975 MHz to 1525 MHz) of the second adapter 26 can be blocked by the shielding component 28 to reduce undesired coupling with signals in the lower frequency range (i.e., 5 MHz to 860 MHz) of the first adapter 24, thereby reducing signal interference between the first and second adapters 24, 26 to improve signal transmission quality and operational stability of equipment connected to the multiplexing device 2. In addition, the surge suppressor 29 connected between the input end 3 and each of the first and second adapters 24, 26 can protect the multiplexing device 2 from damage due to a power surge.

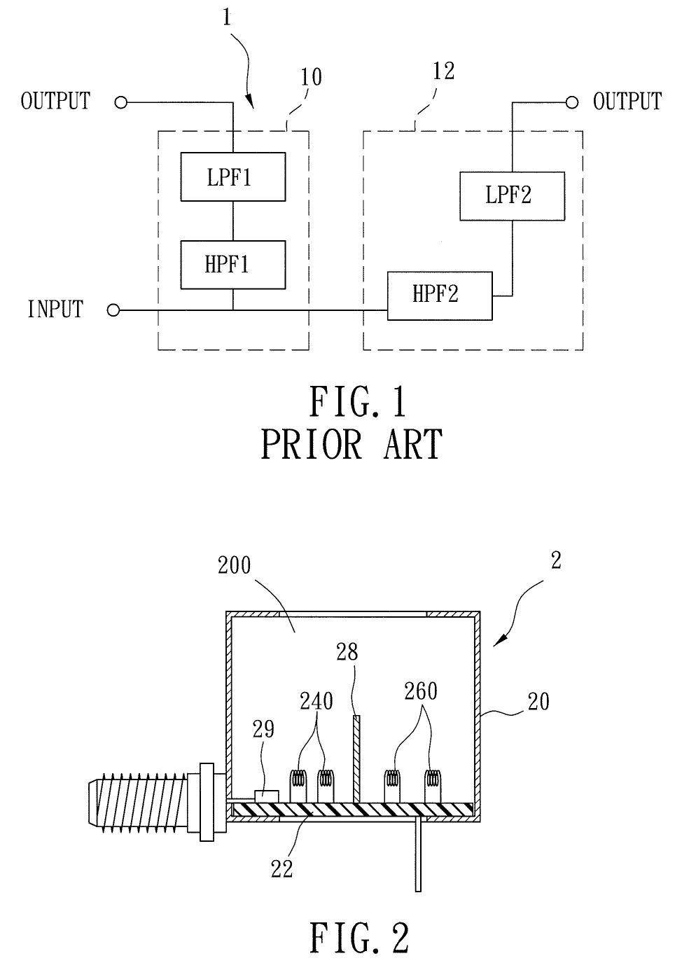

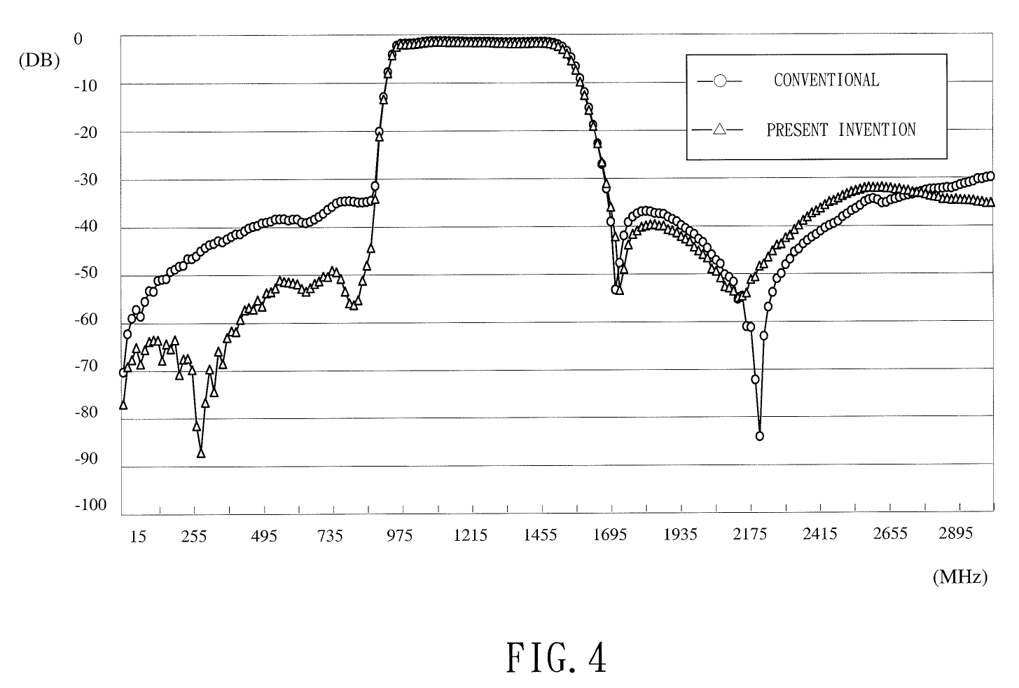

FIG. 4 is a plot of frequency versus noise response to compare the performances of the conventional multiplexer circuit 1 of FIG. 1 and the multiplexing device 2 of the present invention. It is evident from the plot that, for the frequency range of 15 MHz to 855 MHz, the noise response of the multiplexing device 2 of the present invention is better than that of the conventional multiplexer circuit 1, thereby confirming that the shielding component 28 in the multiplexing device 2 of this invention can block electromagnetic energy released by signals in the higher frequency range (i.e., 975 MHz to 1525 MHz) to reduce undesired coupling with signals in the lower frequency range (i.e., 5 MHz to 860 MHz).

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A multiplexing device complying with Multimedia over Coax Alliance (MoCA) specifications and adapted to be disposed between an input end and an output end, said multiplexing device comprising:
a casing;
a circuit board disposed in said casing;
a first adapter disposed on said circuit board and adapted to be connected between the input end and the output end, said first adapter including a first high pass filter and a first low pass filter connected in series to said first high pass filter;
a second adapter disposed on said circuit board and adapted to be connected between the input end and the output end, said second adapter including a second high pass filter and a second low pass filter connected in series to said second high pass filter; and
a shielding component disposed on said circuit board between said first low pass filter of said first adapter and said second low pass filter of said second adapter, said shielding component having a height greater than that of said first and second adapters such that electromagnetic energy emitted by said first and second adapters is blocked to reduce undesired coupling between signals in said first and second adapters.

2. The multiplexing device as claimed in claim 1, wherein said shielding component is in a form of a thin metal plate.

3. The multiplexing device as claimed in claim 1, wherein said first adapter permits signals within the frequency range of 5 MHz to 860 MHz to pass therethrough, and said second adapter permits signals within the frequency range of 975 MHz to 1525 MHz to pass therethrough.

4. The multiplexing device as claimed in claim 1, wherein each of said first high pass filter and said first low pass filter of said first adapter, and said second high pass filter and said second low pass filter of said second adapter is formed from a plurality of coils.

5. The multiplexing device as claimed in claim 1, further comprising a surge suppressor disposed on said circuit board and adapted to be connected between each of said first and second adapters and the input end.
